(19) United States
(12) Patent Application Publication
(10) Pub. No.: US 2020/0177078 A1
(43) Pub. Date: Jun. 4, 2020

(54) SELF-BIASED ACTIVE VOLTAGE DOUBLER FOR ENERGY HARVESTING SYSTEMS

(71) Applicant: KING FAHD UNIVERSITY OF PETROLEUM AND MINERALS, Dhahran (SA)

(72) Inventor: Hussain A. ALZAHER, Dhahran (SA)

(73) Assignee: KING FAHD UNIVERSITY OF PETROLEUM AND MINERALS, Dhahran (SA)

(21) Appl. No.: 16/531,495

(22) Filed: Aug. 5, 2019

Related U.S. Application Data
(60) Provisional application No. 62/774,617, filed on Dec. 3, 2018.

(51) Int. Cl. H02M 3/07; H03F 3/45

(52) U.S. Cl. CPC H02M 3/073; H03F 3/45273; H03F 3/45269

(57) ABSTRACT

An active voltage doubler utilizing a single supply op-amp for energy harvesting system is presented. The active voltage doubler is used for rectification of low power alternating energy sources to achieve both acceptably high power conversion efficiency (PCE) and large rectified DC voltage. The op-amp is self-biased, meaning that no external supply is needed but rather it uses part of the harvested energy for its biasing. Further, the rectified DC voltage is almost twice that of the conventional passive doubler. Power conversion efficiency versus load resistance is plotted and demonstrates that the self-biased active voltage doubler is at least twice as efficient as a conventional passive voltage doubler within the range of 20 to 50 KΩ. The self-biased active voltage doubler achieves maximum power conversion efficiency (PCE) of 61.7% for a 200 Hz sinusoidal input of 0.8V for a 20 KΩ load resistor.

### CROSS REFERENCE TO RELATED APPLICATION

This application is based on and claims the benefit of priority from U.S. Application No. 62/774,617 filed on Dec. 3, 2018, the entire contents of which are incorporated herein by reference.

### STATEMENT OF ACKNOWLEDGEMENT

The authors would like to acknowledge the support provided by the KAUST-KFUPM Initiative (KKI) program, (King Abdullah University of Science and Technology, Thuwal, Saudi Arabia and King Fahd University of Petroleum and Minerals, Riyadh, Saudi Arabia) through Project no. OSR-2016-KKI-001.

### BACKGROUND

### Technical Field

The present disclosure is directed to energy harvesting with a self-biased active voltage doubler.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Energy harvesting has been demonstrated to be a feasible method of augmenting wireless system lifetimes while decreasing dependency on batteries. Surrounding energy, such as radio frequency, solar, and mechanical vibrations, can be utilized as energy sources for energy harvesting. (See M. Ouda, W. Khalil, and K. Salama, “Self-biased differential rectifier with enhanced dynamic range for wireless powering,” IEEE Transactions on Circuits and Systems II: Express Briefs, vol. PP, no. 99, 2016, incorporated herein by reference in its entirety). The exclusion of batteries is beneficial for certain applications such as embedded medical devices and wireless sensor nodes, where inclusion of a battery is expensive or unrealistic. (See H. Xu and M. Ortmanns, “A temperature and process compensated ultralow-voltage rectifier in standard threshold CMOS for energy-harvesting applications.” IEEE Transactions on Circuits and Systems II: Express Briefs, vol. 58, no. 12, pp. 812-816, 2011; and Y. Sun, N. H. Hieu, C.-J. Jeong, and S.-G. Lee, “An integrated high-performance active rectifier for piezoelectric vibration energy harvesting systems,” IEEE Transactions on Power Electronics, vol. 27, no. 2, pp. 623-627, 2012, each incorporated herein by reference in their entirety). Energy scavenging suggests a feasible answer for these applications. Vibration energy based harvesters are very well suited for systems in some technical surroundings, such as buildings, cars, aircraft, and engines. Valuable mechanical vibrations can be found in the frequency band from mHz to kHz. These mechanical vibrations can be transformed into electrical energy using a piezoelectric (PE) generator. (See C. Williams and R. Yates. “Analysis Of A Micro-electric Generator For Microsystems,” in Proceedings of the International Solid-State Sensors and Actuators Conference—TRANSDUCERS '95, pp. 369-372. Stockholm, Sweden, incorporated herein by reference in its entirety). Piezoelectric (PE) energy scavenging systems may provide a high-energy density from 10 μW/cm³ to hundreds of μW/cm³. (See X. D. Do, Y. H. Ko, H. H. Nguyen, H. B. Le, and S. G. Lee, “An efficient parallel SSHI rectifier for piezoelectric energy scavenging systems,” in Proceedings of the IEEE Int. Conf. Adv. Commun, pp. 1394-1397, 2011; Y. K. Ramadass and A. P. Chandrakasan, “An efficient piezoelectric energy harvesting interface circuit using a bias-flip rectifier and shared inductor,” IEEE Journal of Solid-State Circuits, vol. 45, no. 1, pp. 189-204, 2010; and X.-D. Do. H.-H. Nguyen, S.-K. Han. D. S. Ha, and S.-G. Lee, “A self-powered high-efficiency rectifier with automatic resetting of transducer capacitance in piezoelectric energy harvesting systems,” IEEE Transactions on Very Large Scale Integration (VLSI) Systems, vol. 23, no. 3, pp. 444-453, 2015, each incorporated herein by reference in their entirely).

A rectifier, which acts as an interfacing circuit, is required to efficiently convert the output AC signal of a piezoelectric device into a DC signal that can be utilized for operating other circuits or to store the electrical energy for later use. The interfacing circuit is of high importance as it determines the amount of energy extracted by the PE devices.

Various rectifiers have been proposed for piezoelectric energy harvesting systems. A full bridge passive rectifier has been utilized for low frequency PE energy harvesting systems but suffers from poor efficiency. A large voltage drop is not acceptable, thus CMOS diodes or Schottky diodes must be avoided. The voltage drop can be reduced by superimposing a bias voltage onto the gate of the MOS transistor, which eliminates the voltage drop associated with the threshold voltage Vₜₕ. (See S. Guo and H. Lee, “An efficiency-enhanced CMOS rectifier with unbalanced-biased comparators for transcutaneous-powered high-current implants,” IEEE Journal of Solid-State Circuits, vol. 44. no. 6, pp. 1796-1804, 2009, incorporated herein by reference in its entirety). However, adding an extra supply voltage circuit negates the benefit of eliminating the battery.

CMOS active rectifiers are known for low voltage drop and higher power conversion efficiency, PCE. These active rectifiers deliver output voltages almost equal to the input voltage and have lower power consumption. A comparator based diode can be used as an active element to overcome the voltage drop issue for rectifier designs. (See Y. Sun, I. Y. Lee, C. J. Jeong, S. K. Han, and S. G. Lee, “An comparator based active rectifier for vibration energy harvesting systems,” in Proceedings of the IEEE Int. Conf. Adv. Commun. Technol, pp. 1404-1408, 2011; and T. T. Le, J. Han, A. Von Jouanne, K. Mayaram, and T. S. Fiez, “Piezoelectric micro-power generation interface circuits,” IEEE Journal of Solid-State Circuits, vol. 41, no. 6, pp. 1411-1419, 2006, each incorporated herein by reference in their entirety). The rectifier switches are driven by the comparator by sensing the forward voltage drop across the MOS switches. The offset of the comparator causes oscillations (the comparator output leakage in the capacitor) which degrade the PCE of the rectifier design. The solution for this problem has been to replace the comparator based diode with an op-amp based diode. These rectifiers provide a DC rectified voltage often less than amplitude of the AC input voltage. Output voltages of larger amplitudes are usually required for specific low power applications, for example, digital baseband circuits in RFIDs wherein a supply voltage of a 3-5×Vₜₕ is needed. (See K. Kotani, A. Sasaki, and T. Ito, “High-efficiency differential-drive CMOS rectifier for UHF RFIDs.” IEEE Journal of Solid-State Circuits, vol. 44. no. 11, pp. 3011-3018, 2009, incorporated herein by reference in its entirety). The voltage doubler rectifier structure as it provides DC output proportional to twice the approaching input signal amplitude. However, this circuit has low PCE.

Aspects of the present disclosure describe a self-biased active voltage doubler fed by a low frequency piezoelectric transducer or lower frequency antenna, both of which are readily available and provide high output efficiency. A load capacitance is utilized to store the scavenged energy and to bias an active element of the voltage doubler. Therefore, passive diodes may be replaced by active diodes. The self-biased active voltage doubler of the present disclosure achieves large output voltage and high power conversion efficiency.

### SUMMARY

In an exemplary embodiment, self-biased active voltage doubler is disclosed which comprises a clamp capacitor (C_{C}) having a first connection point and a second connection point; a first NMOS transistor (MN₁) having its drain connected to second connection point of the clamp capacitor and its source connected to ground; a load capacitor having a first end and a second end, wherein the second end is connected to ground; a load resistor (R_{L}) connected in parallel with the load capacitor; a second NMOS transistor (MN₂) having its source connected to the second connection point of the clamp capacitor (C_{C}), its source further connected to its gate and its drain connected to the first end of the load capacitor (C_{L}); and an operational amplifier connected at its inverting input to the second connection point of the clamp capacitor (C_{C}), its non-inverting input connected to ground, its positive bias point (V_{bias}) connected to the first end of the load capacitor (C_{L}), its negative bias point connected to ground and its output (Vₒ) connected to the gate of the first NMOS transistor (MN₁).

In another exemplary embodiment active rectifier for use in a self-biased voltage doubler is disclosed, comprising a first NMOS transistor (MN₁) having a gate, a source and a drain; an operational amplifier having an inverting input, a non-inverting input, a positive bias input, a negative bias input and an output; a clamp capacitor having a first connection point and a second connection point, wherein the second connection point is connected to the drain of the first NMOS transistor and the inverting input; wherein the gate of the first NMOS transistor is connected to the output of the operational amplifier (Vₒ) and wherein the source of the first NMOS transistor and the non-inverting input are connected to ground.

In another exemplary embodiment, a method for using a self-biased active voltage doubler to harvest energy is disclosed, comprising providing a source of low power alternating electrical current to charge a clamp capacitor of the a self-biased active voltage doubler to an input voltage, Vᵢₙ; rectifying the current through a first diode connected NMOS transistor whose gate is connected to the output of an op-amp: charging a load capacitor during a first half cycle of the alternating current to a first negative voltage; charging the load capacitor and rectifying the current during a second half cycle of the alternating current to a second negative voltage through a second diode connected NMOS transistor; self-biasing the op-amp at the positive bias point by the voltage of the load capacitor; wherein the voltage of the load capacitor provides the output of the self-biased active voltage doubler and wherein the output voltage Vₒᵤₜ is double the input voltage Vᵢₙ across the clamp capacitor.

The foregoing general description of the illustrative embodiments and the following detailed description thereof are merely exemplary aspects of the teachings of this disclosure, and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 illustrates a traditional passive voltage doubler;

FIG. 2 illustrates a voltage waveform across a first ideal diode;

FIG. 3 illustrates a simple diode-connected voltage doubler;

FIG. 4 illustrates a self-biased active voltage doubler of the present disclosure;

FIG. 5 is a graph illustrating simulated voltage waveforms when Vᵢₙ=0.8 V:

FIG. 6 illustrates a single supply op-amp;

FIG. 7 is a graph illustrating a simulated frequency response of the differential amplifier;

FIG. 8 is a graph illustrating the simulated output voltage with respect to the input voltage;

FIG. 9 is a graph illustrating power conversion efficiency (PCE) as a function of load resistance (R_{L}).

### DETAILED DESCRIPTION

In the drawings, like reference numerals designate identical or corresponding parts throughout the several views. Further, as used herein, the words “a,” “an” and the like generally carry a meaning of “one or more,” unless stated otherwise. The drawings are generally drawn to scale unless specified otherwise or illustrating schematic structures or flowcharts.

Furthermore, the terms “approximately,” “approximate,” “about,” and similar terms generally refer to ranges that include the identified value within a margin of 20%, 10%, or preferably 5%, and any values therebetween.

Aspects of this disclosure are directed to a self-biased active voltage doubler, an active rectifier for use in a self-biased voltage doubler and a for using a self-biased active voltage doubler to harvest energy.

Power originating from vibration energy sources may be unregulated, alternating, and may be small. Therefore, in such situations it is necessary to increase the power conversion efficiency of the rectifier of a voltage doubler. As the output of a precision rectifier can be an the input of a next stage or used to power another active element, larger power conversion efficiency is required so that next stage receives higher DC output voltage at a feasible efficiency. If the power conversion efficiency of the first stage is low, then second stage may not be able to be utilized for further operation.

Maximization of the power conversion efficiency relies on the performance of the rectifier circuit. Enhancement in the power conversion efficiency of the rectifier may be considered as a powerful tool in increase the efficiency of an entire system, as the performance of a front-end is often limited by regional regulation. For example, the maximum power transmission allowed in the Japan and United Stales is 4 W.

The power conversion efficiency (PCE) of a rectifier circuit is defined as the ratio of the output power to the input power. The input power equals the loss in the rectifier plus the output power. Thus, power conversion efficiency can be expressed as

$$PCE = \frac{{P}_{OUT}}{{P}_{IN}} = \frac{{P}_{OUT}}{( {P}_{OUT} + {P}_{LOSS} )} . \qquad ( 1 )$$

Further elaborating on the definition, P_{LOSS} is defined as

P_{LOSS}=N·P_{DIODE}. (2)

P_{DIODE} is the loss in the diode and N is the total number of diode stages. When current flows through the diode, the resistive loss generates a diode loss and is expressed as

P_{DIODE}=P_{FWD}+P_{REV}. (3)

P_{FWD} is the diode forward drop and P_{REF} is the diode reverse drop, which are found from the diode voltage turn-on and the diode leakage reverse current. Therefore, less forward voltage drop and less reverse leakage current are needed to realize a large power conversion efficiency of the harvesting system.

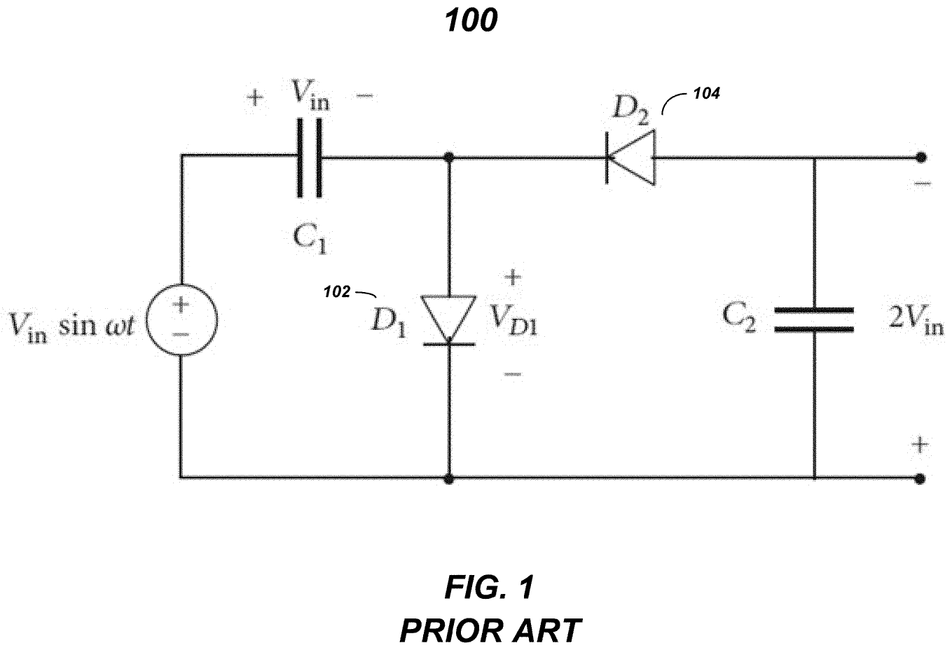

A conventional passive voltage doubler circuit is shown in FIG. 1. (See Adel S. S. and Kenneth C. S., Microelectronic Circuits, Oxford University Press. 6th edition, 2009, incorporated herein by reference in its entirety).

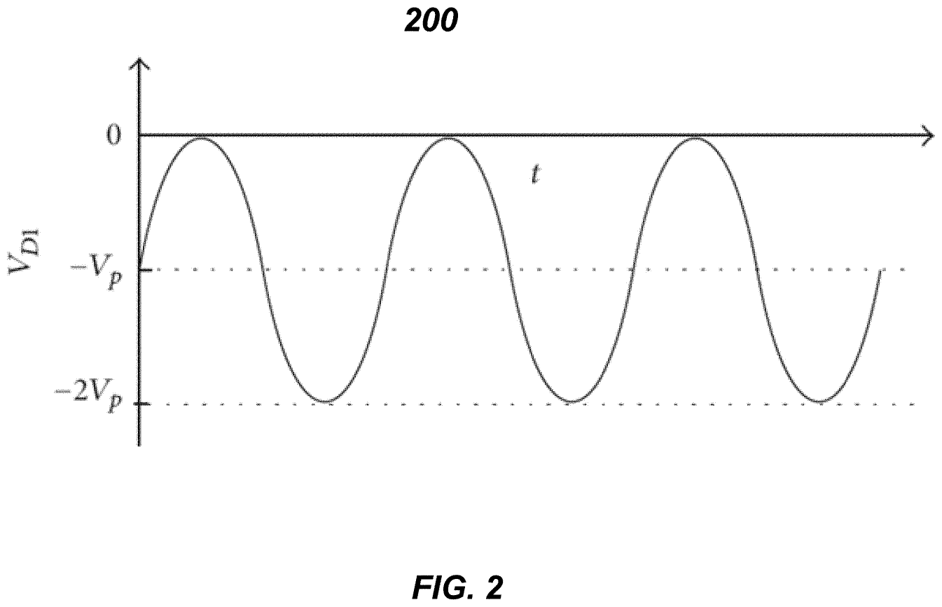

The circuit is a combination of two cascaded parts the clamp circuit formed by C₁ and D₁, and the peak rectifier circuit formed by C₂ and D₂. Diode D₁ 102 conducts during the positive half cycle, storing input voltage in C₁. Assuming ideal diodes, the clamped output voltage V_{D1} is shown in FIG. 2 when a sinusoidal input is applied.

Diode D₂ 104 conducts during the negative half cycle which results in a negative peak of −2Vᵢₙ while the positive peak is clamped to 0V. The output of the peak detector at C₂ yields DC voltage of −2Vᵢₙ. The circuit is known as a voltage doubler since the output voltage, in the ideal case, has twice the amplitude as the input voltage. In practice, the DC output voltage is −2Vᵢₙ plus two forward biased diode voltage drops. For large AC input signals, the diode drops may be neglected. However, the forward biased diode voltage drops represent major loss factors in the output voltage and the efficiency of the circuit.

A diode-connected transistor is a method of creating a two-terminal rectifying device (a diode) out of a three-terminal transistor. A characteristic of diode-connected transistors is that they are always in the saturation region for metal-oxide-semiconductor field-effect transistors (MOSFETs). A diode-connected transistor is made by connecting the gate and drain of a MOSFET.

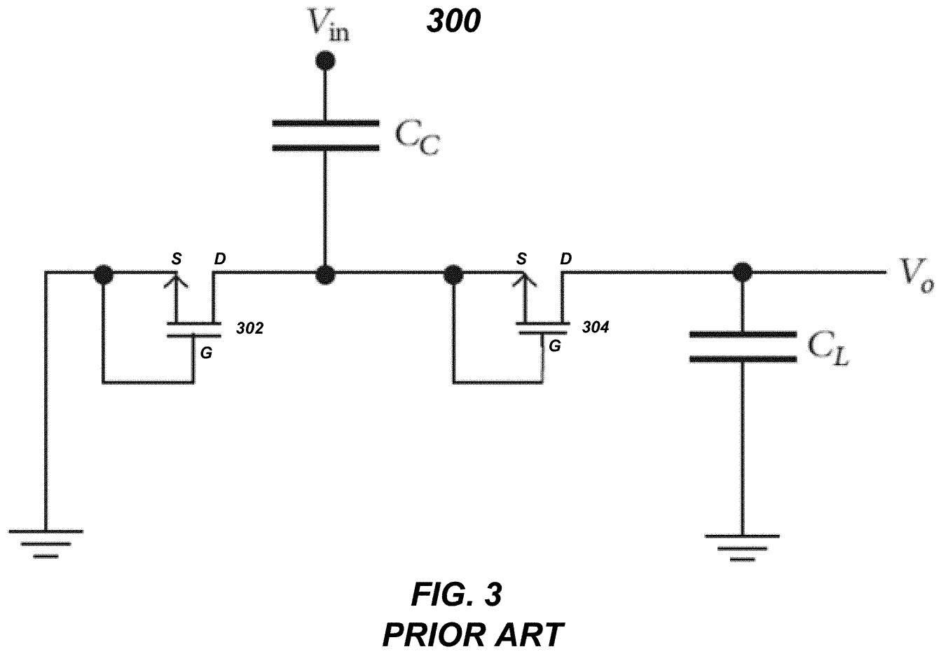

In FIG. 3, the diodes (102, 104) are replaced by diode-connected MOS transistors (302, 304), i.e., their sources (S) are connected to their gates (G). The diode-connected NMOS transistors are attached in series and an intermediate node is linked to the input terminal via coupling capacitor C_{C}.

The effective turn-on voltage of the diode-connected MOS transistor is practically equivalent to Vₜₕ of the MOS transistor, which is smaller than a pn-junction diode, however for the most part larger than a Schottky diode. Thus, a rectifier using this straightforward diode-connected MOS setup achieves neither large voltage nor large power conversion efficiency.

Different energy sources have different types of transducers. An RF transducer is equivalent to an antenna whose power is very small. It may be fed to an impedance matching circuit and a PCB balun to obtain the appropriate AC voltage. (See S. Scorcioni. L. Larcher, and A. Bertacchini, “A reconfigurable differential CMOS RF energy scavenger with 60% peak efficiency and −21 dBm sensitivity,” IEEE Microwave and Wireless Components Letters, vol. 23, no. 3, pp. 155-157, 2013, incorporated herein by reference in its entirety). This voltage signal is then applied to the input of a rectifier. The matching network circuit is not shown, as it is incidental to the self-biased active voltage doubler of the present disclosure.

The piezoelectric transducer (not shown) which generates the alternating voltage commonly includes a cantilever capacitance and is used at a low operating frequency. The type of PE is often called a bimorph. The bimorph is a cantilever used for actuation or sensing which consists of two active layers. It can also have a passive layer between the two active layers. In a non-limiting example, the piezoelectric transducer may be of the type manufactured by Steminc, Steiner & Martins, Inc. and referred to as “Piezo Bimorph Disc Actuator SMBA21T20KP” https://www.steminc.com/PZT/en/piezo-bimorph-disc-actuator-21×20mm. The PE may be an array of piezoelectric transducers. The self-biased active voltage double of the present disclosure is not limited by the source of the electrical signals generated.

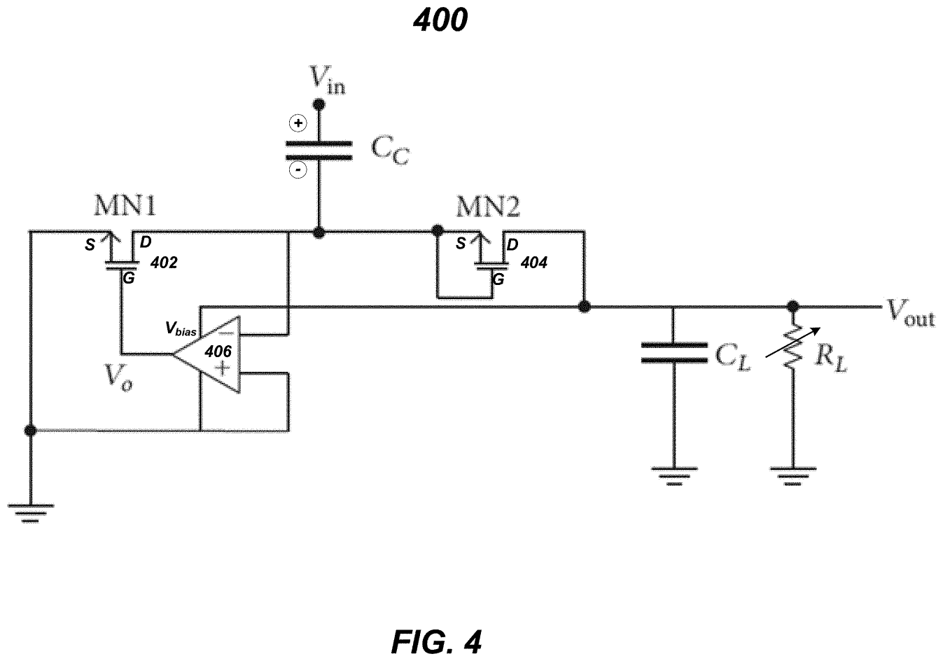

FIG. 4 shows the proposed self-biased active voltage doubler circuit. NMOS transistor MN₁ 402 is connected as a diode (the gate and source are connected) and the circuit has the configuration of an inverting super diode with only one op-amp 406 that is used for the active rectification purpose to achieve large power conversion efficiency. The other NMOS transistor MN₂ 404 is connected to the load capacitance C_{L} and a load resistor R_{L}, thus forming an active voltage doubler. The load resistor R_{L} may be configured as a variable resistance.

There is no additional DC power supply needed to bias the op-amp; instead the bias voltage is obtained from a portion of the harvested energy. Therefore, the op-amp must be biased from a single positive supply with the negative bias connected to ground. The output DC voltage Vₒᵤₜ is connected to V_{dd} of the op-amp, therefore the active voltage doubler circuit is self-biasing due to this incorporated active op-amp.

The active op-amp will not work during start-up as the input voltage is not large enough to supply biasing to the op-amp. The energy stored in the capacitor is small and the op-amp requires a threshold value of DC voltage to operate. Thus, during the startup, the operation of the voltage doubler is governed by the body source voltage of diode MN₁ 402. The active doubler circuit can be modelled as two parallel rectifier stages: a passive rectifier which only works during startup and a high efficiency active rectifier which dominates when the op-amp starts working.

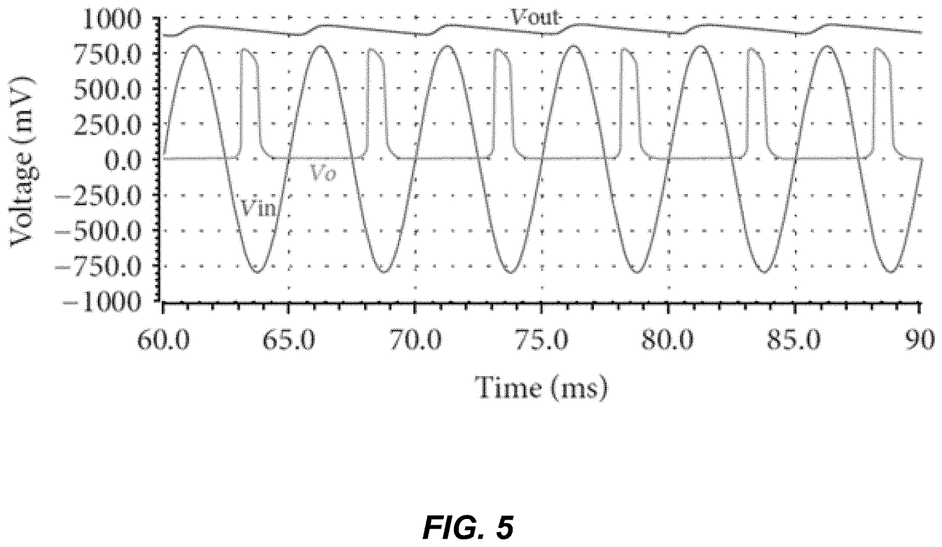

The operation of the self-biased active doubler circuit is explained as follows and is illustrated in FIG. 5. In each input cycle, one of the NMOS diode connected transistors is ON and other is OFF. During startup, when the voltage input cycle is positive, MN₂ is ON, storing energy in C_{L}, while MN₁ is OFF. Note that the source of MN₂ is connected to the negative contact of the capacitor C_{C}. In the negative half cycle, MN₁ conducts due to the body source voltage while MN₂ turns OFF. The energy stored in capacitance C_{L} is fed back to bias the op-amp. The op-amp requires a certain threshold of DC voltage to function properly. The op-amp signal predominates the rectification when the op-amp receives enough voltage to provide its bias. The output Vₒ of the op-amp is connected to the gate of NMOS switch MN₁. When the AC input is positive, the output of the op-amp becomes zero as the configuration is inverting (as the voltage seen by the op-amp at the inverting input is negative), therefore diode connected transistor MN₁ is cut off as its gate voltage is zero. The output of op-amp 406 does not go into the negative saturation level. The op-amp output Vₒ is zero during this half cycle as the op-amp has a single bias supply voltage (due to the grounding of the negative bias point) which reduces the reverse leakage loss. The AC input voltage passes through diode connected transistor MN₂ to charge output storage capacitance C_{L} with some loss due to the ON resistance of the diode connected transistor. When the AC input is negative, the output Vₒ of the op-amp increases, turning MN₁ ON, the voltage drop at MN₁ is reduced and diode connected transistor MN₂ is cut off. The output Vₒᵤₜ decreases slowly and rises again when the next input positive cycle comes.

Simple diode-connected NMOS transistor MN₂ is not configured as a super diode. The principle of the doubler circuit is that only one of the diode connected transistors should be conducting during specific half cycle. If MN₂ is setup as active diode connected transistor as is MN₁, the two diode connected transistors MN₁ and MN₂ would both be either ON or OFF simultaneously during any specific cycle. During a positive half cycle, both transistors would be OFF and both would ON during negative cycle, since both the active diode connected transistors have same type of configuration and are the same type of transistors. Similarly, the same problem occurs even if MN₁ is used as a passive diode connected transistor and MN₂ as an active diode connected transistor and the reason is the same that both active diode connected transistors are simultaneously ON.

Some of the harvested energy is used to operate the op-amp, so its energy consumption should be as small as possible. The main hurdle in op-amp based active rectifiers is that the op-amp itself requires a DC power supply. There are two drawbacks if a DC power supply is used for op-amp. First, an additional element and an additional price are added every time the circuit is utilized for certain application. Second, the addition of an external DC supply means that the system is not truly harvesting energy.

The above-mentioned drawbacks can be eliminated if the DC supply of the op-amp based rectifier is provided by the harvested energy. The stored energy in the capacitor C_{L} supplies the necessary positive DC voltage to bias the op-amp. Hence, the bias voltage of the op-amp must be configured as a single ended supply as only positive DC rectified voltage is fed back from the output of the active doubler. The power consumption of the op-amp must be less that of the rest of the circuit. In this situation, the power conversion efficiency is high.

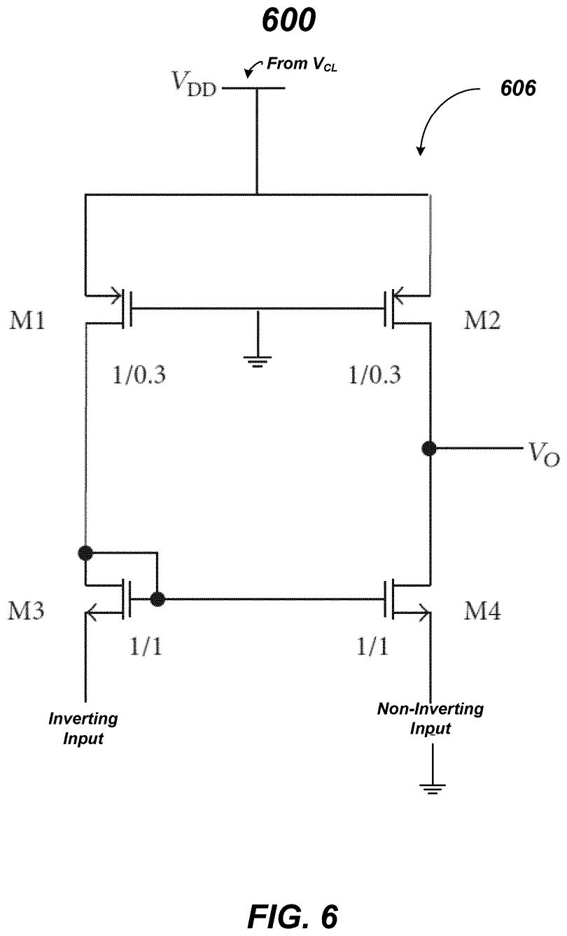

Although the dual supply op-amp is advantageous in some implementations, there are many applications where single supply op-amp is required. For example, in marine and automotive equipment, battery power provides a single supply. One of the main advantages of a single supply op-amp is low power consumption, hence it is useful for low power applications such as biomedical implants and wireless sensor nodes. However, a single supply op-amp needs appropriate signal biasing; otherwise the op-amp becomes unstable or does not provide the desired output. A single supply differential pair MOS configuration is op-amp is used as shown in FIG. 6. (See E. Dallago, D. Miatton, G. Venchi et al., “Active self supplied AC-DC converter for piezoelectric energy scavenging systems with supply independent bias,” in Proceedings of the 2008 IEEE International Symposium on Circuits and Systems, ISCAS 2008, pp. 1448-1451, USA, May 2008, incorporated herein by reference in its entirety).

The op amp 606 as shown in FIG. 6 is ground compatible because the input voltage V_{dd} is fed from storage capacitance as shown in FIG. 4, and the op amp and capacitor are both referenced to ground. The op amp of the present disclosure is designed to work with the lowest possible value of voltage bias. Therefore, the self-biased active voltage doubler performs at a much higher efficiency level than does the prior art passive voltage doubler of FIG. 1 once a low level of charge has been stored in capacitance C_{L}. Matched NMOS input differentials (M₃ and M₄) are used and the non-inverting and inverting inputs are fed into sources of these transistors. The active loads are the PMOS transistors (M₁ and M₂). The sources of these PMOS transistors are connected together and are connected to the DC power supply V_{dd} coming from the storage capacitance C_{L}. All the transistors are in pinch-off condition and the op-amp has been carefully adjusted for best performance.

The first embodiment is illustrated with respect to FIG. 4 and FIG. 6. The first embodiment describes a self-biased active voltage doubler comprising a clamp capacitor (C_{C}) having a first connection point (+) and a second connection point (−); a first NMOS transistor 402 (MN₁) having a drain connected to second connection point of the clamp capacitor and a source connected to ground. A load capacitor (C_{L}) is shown having a first end and a second end, wherein the second end is connected to ground. A load resistor (R_{L}) is connected in parallel with the load capacitor.

A second NMOS transistor (MN₂) has a source connected to the second connection point of the clamp capacitor (C_{C}), a source further connected to a gate and a drain connected to the first end of the load capacitor (C_{L}).

An operational amplifier is connected at an inverting input (see minus sign of 406) to the second connection point of the clamp capacitor (C_{C}), a non-inverting input (see plus sign of 406) connected to ground, a positive bias point (V_{bias}) connected to the first end of the load capacitor (C_{L}), a negative bias point connected to ground and a output (Vₒ) connected to the gate of the first NMOS transistor (MN₁).

The first connection point of the clamp capacitor is connected to a low power source of alternating current, which may be received from a piezoelectric sensor or from a low power antenna.

The operational amplifier comprises a first PMOS transistor (M₁) and a second PMOS transistor (M₂) having their gates connected to ground (note that their gates are tied together in mirror fashion in FIG. 6) and their sources tied together and connected to the first end of the load capacitor C_{L}.

A third NMOS transistor (M₃) has a gate connected to a drain. A drain is connected to the drain of the first PMOS transistor, and a source provides the inverting input of the operational amplifier. A fourth NMOS transistor (M₄) has a drain connected to the drain of the second PMOS transistor and a source connected to ground.

The output (Vₒ) of the operational amplifier is connected to the drains of the fourth NMOS transistor and the second PMOS transistor.

The load resistor (R_{L}) may be a variable resistance.

The second embodiment is illustrated with respect to FIG. 4 and FIG. 6. The second embodiment describes an active rectifier, comprising a first NMOS transistor (MN₁) having a gale, a source and a drain, an operational amplifier having an inverting input, a non-inverting input, a positive bias input, a negative bias input and an output, a clamp capacitor having a first connection point and a second connection point, wherein the second connection point is connected to the drain of the first NMOS transistor and the inverting input. The gate of the first NMOS transistor is connected to the output of the operational amplifier (Vₒ) and the source of the first NMOS transistor and the non-inverting input are connected to ground.

The operational amplifier comprises a first PMOS transistor (M₁) and a second PMOS transistor (M₂) having their gates connected to ground and their sources providing the positive bias input point, a second NMOS transistor (M₃) having a gate connected to a drain, wherein a drain is connected to the drain of the first PMOS transistor, and wherein a source provides the inverting input of the operational amplifier. A third NMOS transistor (M₄) has a drain connected to the drain of the second PMOS transistor and a source connected to ground. The output (Vₒ) of the operational amplifier is connected to the drains of the fourth NMOS transistor and the second PMOS transistor.

The first connection point of the clamp capacitor is connected to a low power source of alternating current, which may be received from a piezoelectric sensor or from a low power antenna.

The third embodiment is illustrated with respect to FIG. 4 to FIG. 6. The first embodiment describes a method for harvesting energy with a self-biased active voltage doubler, and comprises providing a source of low power alternating electrical current to charge a clamp capacitor of the a self-biased active voltage doubler to an input voltage, Vᵢₙ, rectifying the current through a first diode connected NMOS transistor 402 whose gate is connected to the output of an op-amp 406, charging a load capacitor C_{L} during a first half cycle of the alternating current to a first negative voltage, charging the load capacitor and rectifying the current during a second half cycle of the alternating current to a second negative voltage through a second diode connected NMOS transistor, self-biasing the op-amp at the positive bias point by the voltage of the load capacitor, wherein the voltage of the load capacitor provides the output of the self-biased active voltage doubler and wherein the output voltage Vₒᵤₜ is double the input voltage Vᵢₙ across the clamp capacitor.

The method continues by receiving a low power source of alternating current at the first connection point of the clamp capacitor, from either a piezoelectric sensor or a low power antenna.

The method continues by tuning the amplitude of the output voltage Vₒᵤₜ by adjusting a variable resistance connected in parallel with the load capacitor and/or tuning the output resistance by adjusting a variable resistance connected in parallel with the load capacitor.

A more general method of voltage doubling with the self-biased active voltage doubler described above comprises connecting an alternating current power source to the first connection point of the clamp capacitor, thus charging the clamp capacitor, controlling the gate of a first diode connected transistor with the output voltage Vₒ of an operational amplifier, charging the load capacitor by the first diode connected transistor during a first half cycle of the alternating current, charging the load capacitor by the second diode connected transistor during a second half cycle of the alternating current, wherein charging the load capacitor rectifies the alternating current to provide a rectified voltage output, Vₒᵤₜ.

The method of using the self-biased active voltage doubler described above continues by tuning the amplitude of the output voltage Vₒᵤₜ by adjusting a variable resistance connected in parallel with the load capacitor and/or tuning the output resistance by adjusting a variable resistance connected in parallel with the load capacitor.

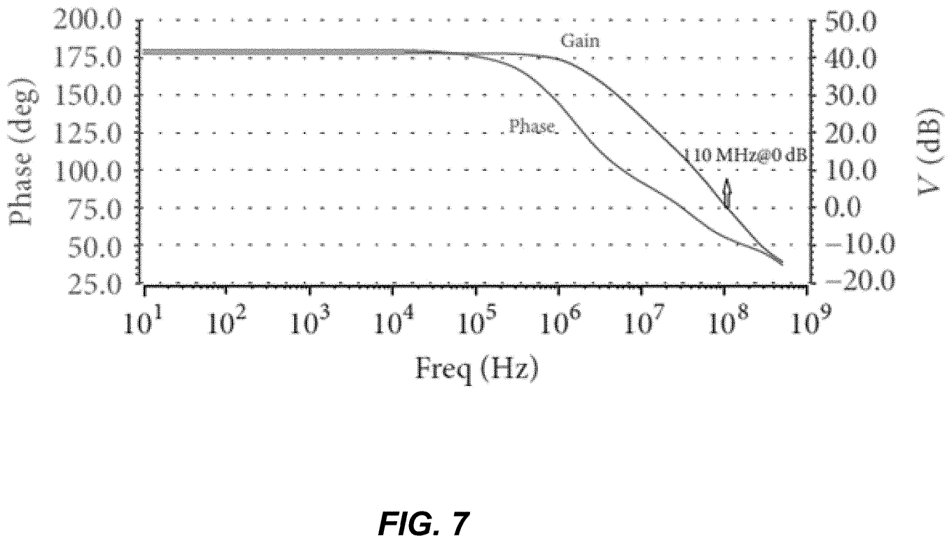

In a non-limiting example of a simulated frequency response analysis, the op-amp is powered with a 0.6V DC supply and transistor widths and lengths are all set to 1 μm except for PMOS active load transistors M₁ and M₂ whose length is set to 0.3 μm. Note that M₁ and M₂ are transistors within the op-amp as shown in FIG. 6 and are not the same as MN₁ and MN₂ of FIG. 4. The gain and phase response of the op-amp 606 are simulated as shown in FIG. 7.

The gain of the op-amp is 41 dB and the unity gain frequency is 110 MHz. The current consumption of the op-amp is 200 nA at 0.6V supply and the current increases with the supply voltage. The DC supply V_{DD} is used for the simulation only. In the design of the present disclosure, the op-amp is self-biased as explained with respect to FIG. 4 and FIG. 6.

The simulation results of the op-amp of FIG. 4 are compared with simulation of the passive voltage doubler circuit of FIG. 1. A piezoelectric (PE) transducer is employed as the input as it provides high output efficiency. PE transducers are able to harvest energy from a button press action and produce high inputs at low frequency. (See X.-D. Do, H.-H. Nguyen, S.-K. Han, and S.-G. Lee, “A rectifier for piezoelectric energy harvesting system with series Synchronized Switch Harvesting Inductor,” in Proceedings of the 2013 9th IEEE Asian Solid-State Circuits Conference, A-SSCC2013, pp. 269-272. Singapore, November 2013, incorporated herein by reference in its entirety). The transducer is simulated by an AC voltage source since the transducer output is an alternating electrical signal. The simulation results demonstrated in this section are carried out using Cadence Virtuoso Simulator with LF 0.15 μm CMOS process technology. The op-amp transistor widths and lengths are all set to 1 μm except for PMOS length which is set at 0.3 μm. The active voltage doubler circuit operates at 200 Hz with a 0.8V input supply. The storage capacitor C_{L} is set to 1 μF and R_{L}=20 KΩ. The NMOS transistor ratios are set to 18μ/0.15μ. The threshold voltages NMOS and PMOS are 0.5V and −0.56V in a standard LF 0.15 μm CMOS process technology.

FIG. 5 shows the voltage waveforms of the simulated self-biased active voltage doubler at steady state. The output voltage is 0.98V with Vᵢₙ=0.8V.

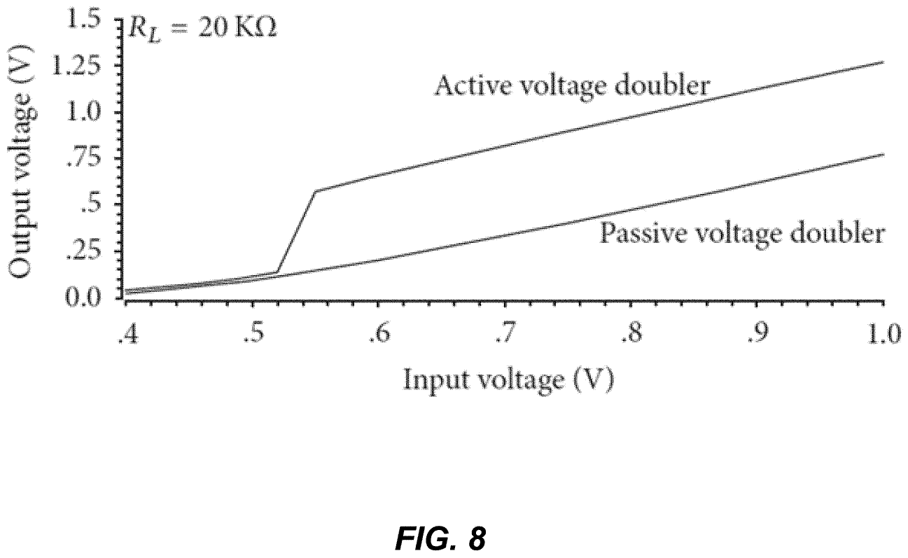

The self-biased active voltage doubler achieves a power conversion efficiency (PCE) of 61.7% at R_{L}=20 KΩ. This efficiency is double that of the passive voltage doubler. A conventional passive voltage doubler yields a PCE of 30% at R_{L}=20 KΩ, with a rectified output voltage of 0.48V, as shown in FIG. 8.

The output voltage graph with respect to the input voltage is simulated and shown in FIG. 8. Below 0.5 V input voltage, the output voltages are negligible, that is, less than 0.1V, and also have less PCE. The output voltage increases sharply beyond 0.5V resulting in higher power conversion efficiency, as the active rectifier begins operating. At 0.6V input voltage, the output voltage is 0.66V with PCE of 57% and then increases linearly with a slope of two for each 0.1V input voltage. At 0.8V the output voltage is 0.98V and continues to increase linearly for higher inputs. The output voltage is compared with that of the passive voltage doubler circuit and gives output voltage of 0.2V with PCE of 17% at 0.6 V input voltage. The output voltages of the self-biased active voltage doubler circuit of the present disclosure are greater than those of the traditional passive voltage doubler for all input range.

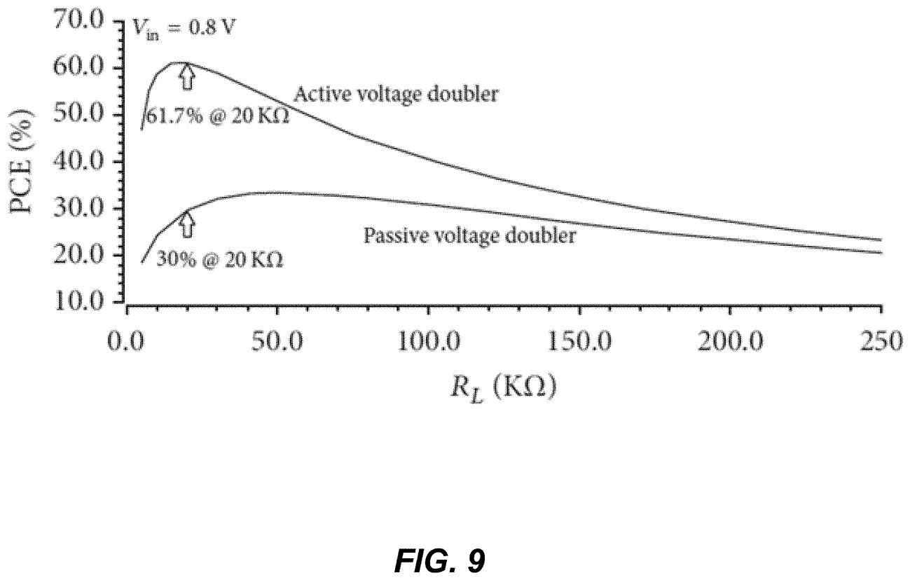

The power conversion efficiency of the self-biased active voltage doubler depends upon the output loading condition (different output loads) and its simulation is demonstrated in FIG. 9. The input amplitude is 0.8V. The active doubler achieves maximum PCE of 61.7% at R_{L}=20 kΩ and it extracts power of 39.36 μW. This relates to input power of about 64 μW (−11.94 dBm). The PCE decreases with the load resistance due to maximum power transfer from impedance matching. When the rectifier input impedance equals the output impedance, maximum power is transferred to the load which leads to the high efficiency of the rectifier at that particular point. When there is variation between the input and output impedances, the PCE varies. The resistance R_{L} is variable, allowing tuning of the output impedance to match the input impedance of a device connected to the active voltage doubler. The variable resistance serves two purposes: it acts to provide output amplitude adjustment as well as output impedance tuning. The power conversion efficiency of the conventional active doubler employing diode-connected MOS transistors (FIG. 3) is 30% at 20 kΩ and it extracts 10.4 μW of power from the piezoelectric vibrations. Further, the self-biased active doubler performs better than the conventional passive voltage doubler for all loads.

Comparison of the self-biased active voltage doubler with previous works can be seen in Table 1. (See Y. Sun, N. H. Hieu, C.-J. Jeong, and S.-G. Lee. “An integrated high-performance active rectifier for piezoelectric vibration energy harvesting systems.” IEEE Transactions on Power Electronics, vol. 27. no. 2, pp. 623-627, 2012; Do et al. “A self-powered high-efficiency rectifier with automatic resetting of transducer capacitance in piezoelectric energy harvesting systems,” IEEE Transactions on Very Large Scale Integration (VLSI) Systems, vol. 23, no. 3. pp. 444-453, 2015); and X.-D. Do. H.-H. Nguyen, S.-K. Han. and S.-G. Lee, “A rectifier for piezoelectric energy harvesting system with series Synchronized Switch Harvesting Inductor,” in Proceedings of the 2013 9th IEEE Asian Solid-State Circuits Conference. A-SSCC2013, pp. 269-272, Singapore, November 2013, each incorporated herein by reference in its entirety).

TABLE 1
COMPARISON WITH PREVIOUS RECTIFIERS

| | | | | Present |
|---|---|---|---|---|
| Reference | (Sun) FIG. 3 | (Do) 2015 | (Do) 2013 | Disclosure |
| Year | 2012 | 2015 | 2013 | 2017 |
| Technology | 0.18 μm | 0.18 μm | 0.35 μm | 0.15 μm |
| Topology | Op-amp based | Self-Powered | Series SSHI | Self-Biased |
| | active rectifier | Rectifier | | Doubler |
| Input | 2.8 V | 3 V | 3.7 V | 0.8 V |
| voltage | | | | |
| Operating | 200 Hz | 200 Hz | 200 Hz | 200 Hz |
| frequency | | | | |
| Output | 2.78 V | 2.9 V | 3.63 V | 0.98 V |
| voltage | | | | |
| Area | 0.24 mm² | 0.016 mm² | 0.016 mm² | 0.001 mm² |
| PCE | 90% | 91.2% | 90% | 61.7% |
| Inductor | No | No | Yes | No |
| Load | R_{L} = 95 kΩ | R_{L} = 100 kΩ | R_{L} = 160 kΩ | R_{L} = 20 KΩ |
| | C_{L} = 1 μF | | | C_{L} = 1 μF |

There are previously known voltage rectifiers which give high efficiency around 90%, however these designs are built for high input voltages (around 3V) and provide lower DC outputs than the input signal amplitudes, thus are not suitable for energy harvesting. The self-biased active voltage doubler of the present disclosure yields 61.7% power efficiency with small input voltages of about 0.8V and yields a rectified output voltage of 0.98V. Therefore, the self-biased active voltage doubler of the present disclosure may be used with low input voltage sources, such as piezoelectric signals from mechanical vibrations, and provides doubled output voltage.

The self-biased active voltage doubler of the present disclosure is suited for low power energy harvesting system applications. The active doubler starts to operate 0.5V input and achieves larger PCE at high inputs. The voltage doubler of the present disclosure achieves power conversion efficiency (PCE) of 61.7% under the condition of 200 Hz operating frequency, 0.8V input signal with a 20 kΩ load resistor. The power conversion efficiency is double that of the passive voltage doubler. The self-biased active voltage doubler circuit has application in biomedical devices and wireless sensor nodes for direct powering or to charge a rechargeable battery. The self-biased active voltage doubler can be scaled to a multistage rectifier circuit design that provides larger DC output voltages to power remote devices while maintaining acceptable power conversion efficiency.

Obviously, numerous modifications and variations of the present invention are possible in light of the above teachings. It is therefore to be understood that within the scope of the appended claims, the invention may be practiced otherwise than as specifically described herein.

1. A self-biased active voltage doubler comprising:
a clamp capacitor (C_{c}) having a first connection point and a second connection point;
a first NMOS transistor (MN₁) having a drain connected to second connection point of the clamp capacitor and a source connected to ground;
a load capacitor having a first end and a second end, wherein the second end is connected to ground;
a load resistor (R_{L}) connected in parallel with the load capacitor;
a second NMOS transistor (MN₂) having a source connected to the second connection point of the clamp capacitor (C_{C}), the source further connected to a gate and a drain connected to the first end of the load capacitor (C_{L}); and
an operational amplifier having an inverting input connected to the second connection point of the clamp capacitor (C_{C}), a non-inverting input connected to ground, a positive bias point (V_{bias}) connected to the first end of the load capacitor (C_{L}), a negative bias point connected to ground and an output (Vₒ) connected to the gate of the first NMOS transistor (MN₁).

2. The self-biased active voltage doubler of claim 1, wherein the first connection point of the clamp capacitor is connected to a low power source of alternating current.

3. The self-biased active voltage doubler of claim 2, wherein the low power source of alternating current is received from a piezoelectric sensor.

4. The self-biased active voltage doubler of claim 2, wherein the low power source of alternating current is received from a low power antenna.

5. The self-biased active voltage doubler of claim 1,
wherein the operational amplifier comprises a first PMOS transistor (M₁) and a second PMOS transistor (M₂), each having a gate connected to ground and a source connected to the first end of the load capacitor C_{L};
a third NMOS transistor (M₃) having a gate connected to a drain, wherein the drain is connected to the drain of the first PMOS transistor, and a source that provides the inverting input of the operational amplifier;
a fourth NMOS transistor (M₄) having a drain connected to the drain of the second PMOS transistor and a source connected to ground;
wherein the output (Vₒ) of the operational amplifier is connected to the drains of the fourth NMOS transistor and the second PMOS transistor.

6. The self-biased active voltage doubler of claim 1, wherein the load resistor (R_{L}) is a variable resistance.

7. An active rectifier, comprising
a first NMOS transistor (MN₁) having a gate, a source and a drain;
an operational amplifier having an inverting input, a non-inverting input, a positive bias input, a negative bias input and an output;
a clamp capacitor having a first connection point and a second connection point, wherein the second connection point is connected to the drain of the first NMOS transistor and the inverting input;
wherein the gate of the first NMOS transistor is connected to the output of the operational amplifier (Vₒ);
wherein the source of the first NMOS transistor and the non-inverting input are connected to ground.

8. The active rectifier of claim 7,
wherein the operational amplifier comprises a first PMOS transistor (M₁) and a second PMOS transistor (M₂) having their gates connected to ground and their sources providing the positive bias input point;
a second NMOS transistor (M₃) having a gate connected to a drain, wherein the drain is connected to the drain of the first PMOS transistor, and wherein the source provides the inverting input of the operational amplifier;
a third NMOS transistor (M₄) having a drain connected to the drain of the second PMOS transistor and a source connected to ground;
wherein the output (Vₒ) of the operational amplifier is connected to the drains of the fourth NMOS transistor and the second PMOS transistor.

9. The active rectifier of claim 7, wherein the first connection point of the clamp capacitor is connected to a low power source of alternating current.

10. The active rectifier of claim 9, wherein the low power source of alternating current is received from a piezoelectric sensor.

11. The active rectifier of claim 9, wherein the low power source of alternating current is received from a low power antenna.

12. A method for harvesting energy with a self-biased active voltage doubler, comprising:
charging a clamp capacitor of a self-biased active voltage doubler by a source of low power alternating electrical current to an input voltage, Vᵢₙ;
rectifying the current through a first diode connected NMOS transistor whose gate is connected to the output of an op-amp;
charging a load capacitor during a first half cycle of the alternating current to a first negative voltage;
charging the load capacitor and rectifying the current during a second half cycle of the alternating current to a second negative voltage through a second diode connected NMOS transistor;
self-biasing the op-amp at the positive bias point by the voltage of the load capacitor;
wherein the voltage of the load capacitor provides the output of the self-biased active voltage doubler; and
wherein the output voltage Vₒᵤₜ is double the input voltage Vᵢₙ across the clamp capacitor.

13. The method for harvesting energy of claim 12, further comprising receiving a low power source of alternating current at the first connection point of the clamp capacitor.

14. The method for harvesting energy of claim 13, further comprising receiving the low power source of alternating current from a piezoelectric sensor.

15. The method for harvesting energy of claim 13, further comprising receiving the low power source of alternating current from a low power antenna.

16. The method for harvesting energy of claim 12, further comprising tuning the amplitude of the output voltage Vₒᵤₜ by adjusting a variable resistance connected in parallel with the load capacitor.

17. The method for harvesting energy of claim 12, further comprising tuning the output resistance by adjusting a variable resistance connected in parallel with the load capacitor.

18. A method of voltage doubling with the self-biased active voltage doubler of claim 1, comprising:
connecting an alternating current power source to the first connection point of the clamp capacitor, thus charging the clamp capacitor;
controlling the gate of a first diode connected transistor with the output voltage Vₒ of an operational amplifier;
charging the load capacitor by the first diode connected transistor during a first half cycle of the alternating current;
charging the load capacitor by the second diode connected transistor during a second half cycle of the alternating current;
wherein charging the load capacitor rectifies the alternating current to provide a rectified voltage output, Vₒᵤₜ.

19. The method of voltage doubling of claim 18, further comprising tuning the output voltage Vₒᵤₜ by adjusting a variable resistance connected in parallel with the load capacitor.

20. The method of voltage doubling of claim 18, further comprising tuning the output resistance by adjusting a variable resistance connected in parallel with the load capacitor.
